(19) United States
(12) Patent Application Publication
(10) Pub. No.: US 2026/0304722 A1
(43) Pub. Date: Oct. 1, 2026

(54) METHOD OF PROVIDING INTRA-MODULE ELECTROMAGNETIC INTERFERENCE SHIELDING TO AN ELECTRONIC PACKAGE MODULE

(71) Applicant: Skyworks Solutions, Inc., Irvine, CA (US)

(72) Inventor: Howard E. Chen, Anaheim, CA (US)

(21) Appl. No.: 19/559,755

(22) Filed: Mar. 6, 2026

Related U.S. Application Data
(60) Provisional application No. 63/770,234, filed on Mar. 11, 2025.
(60) Provisional application No. 63/770,257, filed on Mar. 11, 2025.

(51) Int. Cl. H05K 9/00

(52) U.S. Cl. CPC H05K 9/0032

(57) ABSTRACT

A method of providing intra-module electromagnetic interference shielding includes providing a strip that includes a plurality of electronic package modules spaced apart. The method can include providing an electromagnetic interference shielding arrangement including a preformed shield wall and moving the electromagnetic interference shielding arrangement relative to the strip. The preformed shield wall can be disposed on a surface of the strip. An inner portion of the preformed shield wall can be located within a perimeter of a first module electronic package modules. An outer portion of the preformed shield wall can be located outside the perimeter of the first module. The first module can be separated from the strip so as to fracture the preformed shield wall along the perimeter of the first module. The inner portion can define at least part of an intra-module electromagnetic interference shield for the first module.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/770,234, filed Mar. 11, 2025, titled “METHOD OF PROVIDING INTRA-MODULE ELECTROMAGNETIC INTERFERENCE SHIELDING TO AN ELECTRONIC PACKAGE MODULE,” and U.S. Provisional Patent Application No. 63/770,257, filed Mar. 11, 2025, titled “ELECTRONIC PACKAGE MODULES WITH INTRA-MODULE ELECTROMAGNETIC INTERFERENCE SHIELDING,” are hereby incorporated by reference under 37 CFR 1.57 in their entirety.

### BACKGROUND

### Field

The present disclosure relates to a method of providing intra-module electromagnetic interference shielding to an electronic package module. The present disclosure also relates to a strip of electronic package modules in which one or more of the electronic package modules are provided with intra-module electromagnetic interference shielding.

### Description of the Related Technology

Conventional electronic package modules incorporate intra-module electromagnetic interference shielding arranged over a surface of the module to partially or wholly surround a semiconductor component mounted to the surface of the module. The intra-module electromagnetic interference shielding helps to reduce or prevent electromagnetic radiation emissions from the semiconductor component from interfering with other components of the module or devices external to the module. The intra-module electromagnetic interference shielding also helps to reduce or prevent electromagnetic radiation emissions from other components of the electronic package module or sources external to the module from interfering with operation of the semiconductor component. Known forms of intra-module electromagnetic shielding include wire loop fencing, in which a plurality of groups of wire loops are successively arranged along a surface of an electronic package module to partially or wholly surround a semiconductor component of the module. The plurality of groups of wire loops define a wire shield or fence which acts as an electromagnetic interference shield. Ea wire loop is secured to locations on the surface of the module. Intra-module electromagnetic interference shielding is also known in the form of conductive epoxy disposed in channels formed in a mold structure arranged over the surface of a substrate of the package module. The channels may be arranged to partially or wholly surround a semiconductor component of the electronic package module, with the mold structure at least partially encapsulating the semiconductor component.

### SUMMARY

According to one embodiment, there is provided a method of providing intra-module electromagnetic interference shielding to at least one of a plurality of electronic package modules, the method comprising steps of: providing a strip extending over an area, the strip comprising a plurality of electronic package modules spaced apart from and coupled to each other over the area of the strip; providing an electromagnetic interference shielding arrangement comprising a preformed wall; moving the electromagnetic interference shielding arrangement relative to the strip to dispose the preformed wall on a surface of the strip such that one or more inner portions of the preformed wall are located within a perimeter of a first one of the plurality of electronic package modules and one or more outer portions of the preformed wall are located outside the perimeter of the first electronic package module; separating the first electronic package module from the strip so as to fracture the preformed wall along the perimeter of the first electronic package module, thereby separating the one or more inner portions of the preformed wall from the one or more outer portions of the preformed wall, the one or more inner portions of the preformed wall defining at least part of an intra-module electromagnetic interference shield for the first electronic package module.

In one example, the electromagnetic interference shielding arrangement comprises a reinforcing element coupled to and extending between spatially distinct portions of the preformed wall to enhance structural stiffness of the electromagnetic interference shielding arrangement, wherein the step of moving the electromagnetic interference shielding arrangement relative to the strip comprises engaging a lifting assembly with the reinforcing element to lift and translate the electromagnetic interference shielding arrangement.

In one example, the step of moving the electromagnetic interference shielding arrangement relative to the strip comprises the lifting assembly applying suction to the reinforcing element to gain hold of the electromagnetic interference shielding arrangement.

In one example, the reinforcing element comprises a roof structure extending over the preformed wall, wherein the step of moving the electromagnetic interference shielding arrangement relative to the strip comprises the lifting assembly applying suction to the roof structure to gain hold of the electromagnetic interference shielding arrangement.

In one example, the method comprises steps of: providing a respective electromagnetic interference shielding arrangement for each one of the plurality of electronic package modules, each of the electromagnetic interference shielding arrangements comprising a preformed wall, and for each one of the electromagnetic interference shielding arrangements, moving the electromagnetic interference shielding arrangement relative to the strip to dispose the respective preformed wall on the surface of the strip such that one or more inner portions of the preformed wall are located within a perimeter of the corresponding electronic package module and one or more outer portions of the preformed wall are located outside the perimeter of the corresponding electronic package module; separating each of the plurality of electronic package modules from the strip so as to fracture the respective preformed wall along the perimeter of the corresponding electronic package module, the one or more inner portions of the respective preformed wall defining at least part of an intra-module electromagnetic interference shield for the corresponding electronic package module.

In one example, the step of moving the electromagnetic interference shielding arrangement relative to the strip to dispose the preformed wall on a surface of the strip is performed such that the one or more outer portions of the preformed wall extend over a saw street of the strip.

In one example, the saw street is disposed between the first electronic package module and an adjacent one or more of the plurality of electronic package modules.

In one example, the step of moving the electromagnetic interference shielding arrangement relative to the strip to dispose the preformed wall on a surface of the strip is performed such that the one or more outer portions of the preformed wall are confined to the saw street.

In one example, the step of moving the electromagnetic interference shielding arrangement relative to the strip to dispose the preformed wall on a surface of the strip is performed such that the one or more outer portions of the preformed wall extend beyond the saw street over a surface of an adjacent one or more of the plurality of electronic package modules.

In one example, the step of providing an electromagnetic interference shielding arrangement comprising a preformed wall comprises providing the preformed wall to define a continuous path.

In one example, the step of providing an electromagnetic interference shielding arrangement comprising a preformed wall comprises providing the preformed wall to define a shape having three, four, or more sides.

In one example, the step of providing an electromagnetic interference shielding arrangement comprising a preformed wall comprises providing the preformed wall to define an open-ended path extending between first and second free ends.

In one example, the step of moving the electromagnetic interference shielding arrangement relative to the strip to dispose the preformed wall on a surface of the strip is performed such that one or both of the first and second free ends are located outside of the perimeter of the first electronic package module.

In one example, the step of providing an electromagnetic interference shielding arrangement comprising a preformed wall comprises providing the preformed wall as configured to be self-supporting when disposed on the surface of the strip.

In one example, the step of providing an electromagnetic interference shielding arrangement comprising a preformed wall comprises providing the preformed wall as comprising or consisting of first and second linear wall sections, the first and second linear wall sections being non-colinear relative to each other.

In one example, the step of providing an electromagnetic interference shielding arrangement comprising a preformed wall comprises providing the preformed wall as extending over a curved path between the first and second free ends.

In one example, the method further comprises a step of applying a mold structure over the surface of the strip to at least partially embed the electromagnetic interference shielding arrangement in the mold structure.

In one example, the step of applying a mold structure over the surface of the strip comprises applying the mold structure over substantially the entire area of the strip.

In one example, the step of applying a mold structure over the surface of the strip is performed to flow material of the mold structure through one or more cut-outs or apertures defined through the electromagnetic interference shielding arrangement.

In one example, the step of applying a mold structure over the surface of the strip is performed to flow material of the mold structure through one or more cut-outs or apertures defined through a thickness of the preformed wall.

In one example, the step of applying a mold structure over the surface of the strip is performed to flow material of the mold structure through one or more cut-outs or apertures defined through a thickness of a roof structure of the electromagnetic interference shielding arrangement.

In one example, the step of applying a mold structure over the surface of the strip is performed such that the mold structure covers a roof structure of the electromagnetic interference shielding arrangement.

In one example, the method further comprises: a step of removing part of the mold structure to expose the roof structure; and a step of applying a conformal electromagnetic interference shield over an exterior of the first electronic package module such that the conformal electromagnetic interference shield is in surface contact with the exposed roof structure.

In one example, the method further comprises: a step of removing part of the mold structure and all of the roof structure to expose the preformed wall through the mold structure; and a step of applying a conformal electromagnetic interference shield over an exterior of the first electronic package module such that the conformal electromagnetic interference shield is in surface contact with the exposed preformed wall.

In one example, the step of moving the electromagnetic interference shielding arrangement relative to the strip to dispose the preformed wall on a surface of the strip comprises a step of securing the preformed wall to a surface of the first electronic package module.

In one example, the step of securing the preformed wall to a surface of the first electronic package module comprises securing the preformed wall to one or more electrically conductive interfaces of a substrate panel portion of the first electronic package module.

In one example, the step of moving the electromagnetic interference shielding arrangement relative to the strip to dispose the preformed wall on a surface of the strip is performed such that the one or more inner portions of the preformed wall at least partially surround a semiconductor component of the first electronic package module.

In one example, the step of providing a strip extending over an area comprises providing the strip to comprise a substrate panel extending over substantially the entire area of the strip, each of the plurality of electronic package modules comprising a spatially distinct, respective portion of the substrate panel.

In one example, the step of providing an electromagnetic interference shielding arrangement comprising a preformed wall comprises providing the preformed wall as substantially formed of an electrically conductive material.

In one example, the step of providing an electromagnetic interference shielding arrangement comprising a preformed wall comprises providing the preformed wall as substantially formed of a metallic material.

In one example, the metallic material comprises or consists of copper or aluminium.

According to another embodiment, there is provided a strip of electronic package modules comprising: a plurality of electronic package modules spaced apart from and coupled to each other over an area of the strip; an electromagnetic interference shielding arrangement comprising a preformed wall, the preformed wall disposed on a surface of the strip, one or more inner portions of the preformed wall located within a perimeter of a first one of the plurality of electronic package modules and one or more outer portions of the preformed wall located outside the perimeter of the first electronic package module, the one or more inner portions of the preformed wall defining at least part of an intra-module electromagnetic interference shield for the first electronic package module.

In one example, the electromagnetic interference shielding arrangement comprises a reinforcing element coupled to and extending between spatially distinct portions of the preformed wall to enhance structural stiffness of the electromagnetic interference shielding arrangement.

In one example, the reinforcing element comprises a roof structure extending over the preformed wall.

In one example, the roof structure is substantially planar.

In one example, the electromagnetic interference shielding arrangement comprises one or more cut-outs or apertures extending through a thickness of the roof structure and/or the preformed wall.

In one example, the strip comprises: a respective electromagnetic interference shielding arrangement corresponding to each one of the plurality of electronic package modules, each of the electromagnetic interference shielding arrangements comprising a preformed wall; for each one of the electromagnetic interference shielding arrangements, the respective preformed wall is disposed on the surface of the strip such that one or more inner portions of the preformed wall are located within a perimeter of the corresponding electronic package module and one or more outer portions of the preformed wall are located outside the perimeter of the corresponding electronic package module, the one or more inner portions of the preformed wall defining at least part of an intra-module electromagnetic interference shield for the corresponding electronic package module.

In one example, the one or more outer portions of the preformed wall extend over a saw street of the strip.

In one example, the saw street is disposed between the first electronic package module and an adjacent one or more of the plurality of electronic package modules.

In one example, the one or more outer portions of the preformed wall are confined to the saw street.

In one example, the one or more outer portions of the preformed wall extend beyond the saw street over a surface of an adjacent one or more of the plurality of electronic package modules.

In one example, the preformed wall defines a continuous path.

In one example, the preformed wall defines a shape having three, four, or more sides.

In one example, the preformed wall defines an open-ended path extending between first and second free ends.

In one example, one or both of the first and second free ends are located outside of the perimeter of the first electronic package module.

In one example, the preformed wall is configured to be self-supporting on the surface of the strip.

In one example, the preformed wall comprises or consists of first and second linear wall sections, the first and second linear wall sections being non-colinear relative to each other.

In one example, the preformed wall extends over a curved path between the first and second ends.

In one example, the electromagnetic interference shielding arrangement is at least partially embedded in a mold structure arranged over the surface of the strip.

In one example, the electromagnetic interference shielding arrangement extends proud of an exterior-facing surface of the mold structure.

In one example, the electromagnetic interference shielding arrangement is flush with an exterior-facing surface of the mold structure.

In one example, the preformed wall is secured to a surface of the first electronic package module.

In one example, the preformed wall is secured to one or more electrically conductive interfaces of a substrate panel portion of the first electronic package module.

In one example, the one or more inner portions of the preformed wall at least partially surround a semiconductor component of the first electronic package module.

In one example, the strip comprises a substrate panel extending over substantially the entire area of the strip, each of the plurality of electronic package modules comprising a spatially distinct, respective portion of the substrate panel.

In one example, the preformed wall is substantially formed of an electrically conductive material.

In one example, the preformed wall is substantially formed of a metallic material.

In one example, the metallic material comprises or consists of copper or aluminium.

In some aspects, the techniques described herein relate to a method of providing intra-module electromagnetic interference shielding, the method including: providing a strip including a plurality of electronic package modules spaced apart from each other; providing an electromagnetic interference shielding arrangement including a shield wall to dispose the shield wall on a surface of the strip such that an inner portion of the shield wall is located within a perimeter of a first module of the plurality of electronic package modules and an outer portion of the shield wall is located outside the perimeter of the first module; and separating the first module from the strip so as to fracture the shield wall along the perimeter of the first module, thereby separating the inner portion of the shield wall from the outer portion of the shield wall, the inner portion of the shield wall defining at least part of an intra-module electromagnetic interference shield for the first module.

In some embodiments, the techniques described herein relate to a method wherein the electromagnetic interference shielding arrangement further includes a reinforcing element coupled to and extending between spatially distinct portions of the shield wall to enhance structural stiffness of the electromagnetic interference shielding arrangement, wherein providing the electromagnetic interference shielding arrangement includes engaging a lifting assembly with the reinforcing element to lift and translate the electromagnetic interference shielding arrangement.

In some embodiments, the techniques described herein relate to a method wherein providing the electromagnetic interference shielding arrangement further includes applying suction to the reinforcing element by the lifting assembly to hold the electromagnetic interference shielding arrangement.

In some embodiments, the techniques described herein relate to a method wherein the reinforcing element includes a roof structure extending over the shield wall, wherein providing the electromagnetic interference shielding arrangement includes applying suction to the roof structure by the lifting assembly to hold the electromagnetic interference shielding arrangement.

In some embodiments, the techniques described herein relate to a method further including: providing a second electromagnetic interference shielding arrangement for a second module of the plurality of electronic package modules, the second electromagnetic interference shielding arrangement includes a second shield wall, and wherein providing the second electromagnetic interference shielding arrangement includes moving the electromagnetic interference shielding arrangement to dispose the second shield wall such that an inner portion of the second shield wall is located within a perimeter of the second module and an outer portion of the second shield wall is located outside the perimeter of the second module; and separating the second module from the strip so as to fracture the second shield wall along the perimeter of the second module, the inner portion of the second shield wall defining at least part of the intra-module electromagnetic interference shield for the second module.

In some embodiments, the techniques described herein relate to a method wherein providing the electromagnetic interference shielding arrangement is performed such that the outer portion of the shield wall extends over a saw street of the strip.

In some embodiments, the techniques described herein relate to a method wherein the saw street is disposed between the first module and an adjacent one or more of the plurality of electronic package modules.

In some embodiments, the techniques described herein relate to a method wherein providing the electromagnetic interference shielding arrangement is performed such that the outer portion of the shield wall is confined to the saw street.

In some embodiments, the techniques described herein relate to a method wherein providing the electromagnetic interference shielding arrangement is performed such that the outer portion of the shield wall extends beyond the saw street.

In some embodiments, the techniques described herein relate to a method wherein providing the electromagnetic interference shielding arrangement includes providing the shield wall to define a continuous path.

In some embodiments, the techniques described herein relate to a method wherein providing the electromagnetic interference shielding arrangement includes providing the shield wall to define a shape having three, four, or more sides.

In some embodiments, the techniques described herein relate to a method wherein providing the electromagnetic interference shielding arrangement includes providing the shield wall to define an open-ended path extending between first and second free ends.

In some embodiments, the techniques described herein relate to a method wherein providing the electromagnetic interference shielding arrangement is performed such that one or both of the first and second free ends are located outside of the perimeter of the first module.

In some embodiments, the techniques described herein relate to a method wherein providing the electromagnetic interference shielding arrangement includes providing the shield wall as configured to be self-supporting when disposed on the surface of the strip.

In some embodiments, the techniques described herein relate to a method wherein the shield wall includes first and second linear wall sections, the first and second linear wall sections being non-colinear relative to each other.

In some embodiments, the techniques described herein relate to a method wherein the shield wall extends over a curved path between the first and second free ends.

In some embodiments, the techniques described herein relate to a method further including applying a mold structure over the surface of the strip to at least partially embed the electromagnetic interference shielding arrangement in the mold structure.

In some embodiments, the techniques described herein relate to a method wherein applying the mold structure includes applying the mold structure over substantially the entire area of the strip.

In some embodiments, the techniques described herein relate to a method wherein applying the mold structure is performed to flow material of the mold structure through one or more cut-outs or apertures defined through the electromagnetic interference shielding arrangement.

In some embodiments, the techniques described herein relate to a method wherein applying the mold structure is performed to flow material of the mold structure through one or more cut-outs or apertures defined through a thickness of the shield wall.

In some embodiments, the techniques described herein relate to a method wherein applying the mold structure is performed to flow material of the mold structure through one or more cut-outs or apertures defined through a thickness of a roof structure of the electromagnetic interference shielding arrangement.

In some embodiments, the techniques described herein relate to a method wherein applying the mold structure is performed such that the mold structure covers a roof structure of the electromagnetic interference shielding arrangement.

In some embodiments, the techniques described herein relate to a method further including: removing part of the mold structure to expose the roof structure; and applying a conformal electromagnetic interference shield over an exterior of the first electronic package module such that the conformal electromagnetic interference shield is in surface contact with the exposed roof structure.

In some embodiments, the techniques described herein relate to a method further including: removing part of the mold structure and all of the roof structure to expose the shield wall through the mold structure; and applying a conformal electromagnetic interference shield over an exterior of the first electronic package module such that the conformal electromagnetic interference shield is in surface contact with the exposed shield wall.

In some embodiments, the techniques described herein relate to a method wherein providing the electromagnetic interference shielding arrangement includes securing the shield wall to a surface of the first module.

In some embodiments, the techniques described herein relate to a method wherein securing the shield wall to the surface of the first module includes securing the shield wall to one or more electrically conductive interfaces of a substrate panel portion of the first module.

In some embodiments, the techniques described herein relate to a method wherein providing the electromagnetic interference shielding arrangement is performed such that the inner portion of the shield wall at least partially surrounds a semiconductor component of the first module.

In some embodiments, the techniques described herein relate to a method wherein the strip includes a substrate panel extending over substantially the entire area of the strip, each of the plurality of electronic package modules including a spatially distinct, respective portion of the substrate panel.

In some embodiments, the techniques described herein relate to a method wherein the shield wall is substantially formed of an electrically conductive material.

In some embodiments, the techniques described herein relate to a method wherein the shield wall is substantially formed of a metallic material.

In some embodiments, the techniques described herein relate to a method wherein the metallic material includes copper or aluminium.

In some aspects, the techniques described herein relate to a method of forming an intra-module electromagnetic interference shielding structure, the method including: providing a strip including a first electronic package module and a second electronic package module spaced from the first electronic package module by a singulation line; providing an electromagnetic interference shielding arrangement including a first portion over the first electronic package module and a second portion over the singulation line; and singulating the first electronic package module along the singulation line thereby fracturing the second portion while keeping the first portion with the first electronic package module to define the intra-module electromagnetic interference shielding structure.

In some embodiments, the techniques described herein relate to a method wherein the intra-module electromagnetic interference shielding structure includes a shield wall and a shield roof.

In some aspects, the techniques described herein relate to a method of forming an intra-module electromagnetic interference shielding structure, the method including: providing a strip including a first electronic package module and a second electronic package module spaced from the first electronic package module by a singulation line; providing an electromagnetic interference shielding arrangement including a first portion over the first electronic package module, a second portion over the singulation line, and a third portion over the second electronic package module; and singulating the first electronic package module and the second electronic package module along the singulation line thereby fracturing the second portion while keeping the first portion with the first electronic package module to define a first intra-module electromagnetic interference shielding structure, and keeping the third portion with the second electronic package module to define a second intra-module electromagnetic interference shielding structure.

In some embodiments, the techniques described herein relate to a method wherein the second portion extends between and connects the first portion and the third portion prior to singulating the first electronic package module and the second electronic package module.

In some aspects, the techniques described herein relate to a strip of electronic package modules including: a plurality of electronic package modules spaced apart from each other; and an electromagnetic interference shielding arrangement including a shield wall, the shield wall disposed on a surface of the strip, an inner portion of the shield wall located within a perimeter of a first module of the plurality of electronic package modules and an outer portion of the shield wall located outside the perimeter of the first module, the inner portion of the shield wall defining at least part of an intra-module electromagnetic interference shield for the first module.

In some embodiments, the techniques described herein relate to a strip wherein the electromagnetic interference shielding arrangement includes a reinforcing element coupled to and extending between spatially distinct portions of the shield wall to enhance structural stiffness of the electromagnetic interference shielding arrangement.

In some embodiments, the techniques described herein relate to a strip wherein the reinforcing element includes a roof structure extending over the shield wall.

In some embodiments, the techniques described herein relate to a strip wherein the roof structure is substantially planar.

In some embodiments, the techniques described herein relate to a strip wherein the electromagnetic interference shielding arrangement includes one or more cut-outs or apertures extending through a thickness of the roof structure and/or the shield wall.

In some embodiments, the techniques described herein relate to a strip further including: a second electromagnetic interference shielding arrangement for a second module of the plurality of electronic package modules, the second electromagnetic interference shielding arrangement includes a second shield wall; and the second shield wall is disposed on the surface of the strip such that an inner portion of the second shield wall is located within a perimeter of the second module and an outer portion of the second shield wall is located outside the perimeter of the second module, the inner portion of the second shield wall defining at least part of a second intra-module electromagnetic interference shield for the second module.

In some embodiments, the techniques described herein relate to a strip wherein the outer portion of the shield wall extends over a saw street of the strip.

In some embodiments, the techniques described herein relate to a strip wherein the saw street is disposed between the first module and an adjacent one or more of the plurality of electronic package modules.

In some embodiments, the techniques described herein relate to a strip wherein the outer portion of the shield wall is confined to the saw street.

In some embodiments, the techniques described herein relate to a strip wherein the outer portion of the shield wall extends beyond the saw street over a surface of an adjacent one or more of the plurality of electronic package modules.

In some embodiments, the techniques described herein relate to a strip wherein the shield wall defines a continuous path.

In some embodiments, the techniques described herein relate to a strip wherein the shield wall defines a shape having three, four or more sides.

In some embodiments, the techniques described herein relate to a strip wherein the shield wall defines an open-ended path extending between first and second free ends.

In some embodiments, the techniques described herein relate to a strip wherein one or both of the first and second free ends are located outside of the perimeter of the first module.

In some embodiments, the techniques described herein relate to a strip wherein the shield wall is configured to be self-supporting on the surface of the strip.

In some embodiments, the techniques described herein relate to a strip wherein the shield wall includes first and second linear wall sections, the first and second linear wall sections being non-colinear relative to each other.

In some embodiments, the techniques described herein relate to a strip wherein the shield wall extends over a curved path between the first and second ends.

In some embodiments, the techniques described herein relate to a strip wherein the electromagnetic interference shielding arrangement is at least partially embedded in a mold structure arranged over the surface of the strip.

In some embodiments, the techniques described herein relate to a strip wherein the electromagnetic interference shielding arrangement extends proud of an exterior-facing surface of the mold structure.

In some embodiments, the techniques described herein relate to a strip wherein the electromagnetic interference shielding arrangement is flush with an exterior-facing surface of the mold structure.

In some embodiments, the techniques described herein relate to a strip wherein the shield wall is secured to a surface of the first module.

In some embodiments, the techniques described herein relate to a strip wherein the shield wall is secured to one or more electrically conductive interfaces of a substrate panel portion of the first module.

In some embodiments, the techniques described herein relate to a strip wherein the inner portion of the shield wall at least partially surrounds a semiconductor component of the first module.

In some embodiments, the techniques described herein relate to a strip wherein the strip includes a substrate panel extending over substantially the entire area of the strip, each of the plurality of electronic package modules includes a spatially distinct, respective portion of the substrate panel.

In some embodiments, the techniques described herein relate to a strip wherein the shield wall is substantially formed of an electrically conductive material.

In some embodiments, the techniques described herein relate to a strip wherein the shield wall is substantially formed of a metallic material.

In some embodiments, the techniques described herein relate to a strip wherein the metallic material includes or consists of copper or aluminium.

In some aspects, the techniques described herein relate to an electronic package module including: a substrate; semiconductor components mounted on the substrate, the semiconductor components including a first component and a second component; and an intra-module electromagnetic interference shielding structure at least partially positioned between the first component and the second component and providing electromagnetic interference shielding for the first component, a wall edge of the intra-module electromagnetic interference shielding structure aligned with a side edge of the substrate.

In some embodiments, the techniques described herein relate to an electronic package module wherein the wall edge has a physical structure that is indicative of separation from a larger structure during a singulation process. 65. 66.

In some embodiments, the techniques described herein relate to an electronic package module wherein the wall edge of the intra-module electromagnetic interference shielding structure exhibits surface features characteristic of mechanical sawing.

In some embodiments, the techniques described herein relate to an electronic package module, wherein the wall edge of the intra-module electromagnetic interference shielding structure exhibits a heat-affected zone characteristic of laser cutting.

In some aspects, the techniques described herein relate to an electronic package module including: a substrate; semiconductor components mounted on the substrate, the semiconductor components including a first component and a second component; and an intra-module electromagnetic interference shielding structure at least partially positioned between the first component and the second component and providing electromagnetic interference shielding for the first component, a wall edge of the intra-module electromagnetic interference shielding structure having a physical structure that is indicative of separation from a larger structure during a singulation process. 70.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment”, “some embodiments”, “an alternate embodiment”, “various embodiments”, “one embodiment” or the like are not necessarily mutually exclusive and are intended to indicate that a particular feature, structure, or characteristic described may be included in at least one embodiment. The appearances of such terms herein are not necessarily all referring to the same embodiment.

The present disclosure relates to U.S. patent application Ser. No. ______ [Attorney Docket SKYWRKS. 1630A2], titled “ELECTRONIC PACKAGE MODULES WITH INTRA-MODULE ELECTROMAGNETIC INTERFERENCE SHIELDING,” filed on even date herewith, the entire disclosure of which is hereby incorporated by reference herein.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a perspective schematic view of an electronic package module according to the background art.

FIG. 2 is a perspective schematic view of a strip of electronic package modules and a plurality of electromagnetic interference shield arrangements for mounting to respective ones of the modules according to an embodiment of the present disclosure;

FIG. 3 is a perspective schematic view of the strip of electronic package modules of FIG. 2 after the plurality of electromagnetic interference shield arrangements have been mounted on their respective modules;

FIG. 4 is a plan schematic view of the strip of electronic package modules of FIG. 3;

FIG. 5 is a plan schematic view of one of the electronic package modules of FIGS. 3 and 4 after the module has been separated from the strip;

FIG. 6 is a cross-sectional schematic view of the electronic package module of FIG. 5 through section B-B, where a lower side of the electronic package module is formed with a land grid array;

FIG. 7 illustrates a variant of the electronic package module of FIG. 6 in which a roof structure of the electromagnetic interference shield arrangement is retained;

FIG. 8 is a cross-sectional schematic view of the electronic package module of FIG. 5 through section B-B for a dual-sided molded ball grid array variant of the package module;

FIG. 9 is a cross-sectional schematic view of the electronic package module of FIG. 8 mounted to a separate circuit board to form an electronic sub-assembly;

FIG. 10 is a perspective schematic view of a strip of electronic package modules and a plurality of electromagnetic interference shield arrangements for mounting to respective ones of the modules according to a further embodiment of the present disclosure;

FIG. 11 is a perspective schematic view of the strip of electronic package modules of FIG. 10 after the plurality of electromagnetic interference shield arrangements have been mounted on their respective modules;

FIG. 12 is a plan schematic view of the strip of electronic package modules of FIG. 11;

FIG. 13 is a plan schematic view of one of the electronic package modules of FIGS. 11 and 12 after the module has been separated from the strip;

FIG. 14 is a cross-sectional schematic view of the electronic package module of FIG. 13 through section C-C, where a lower side of the electronic package module is formed with a land grid array;

FIG. 15 illustrates a variant of the electronic package module of FIG. 14 in which a roof structure of the electromagnetic interference shield arrangement is retained;

FIG. 16 is a cross-sectional schematic view of the electronic package module of FIG. 13 through section C-C for a dual-sided molded ball grid array variant of the package module;

FIG. 17 is a perspective schematic view of a strip of electronic package modules and a plurality of electromagnetic interference shield arrangements for mounting to respective ones of the modules according to a further embodiment of the present disclosure;

FIG. 18 is a perspective schematic view of the strip of electronic package modules of FIG. 17 after the plurality of electromagnetic interference shield arrangements have been mounted on their respective modules;

FIG. 19 is a plan schematic view of the strip of electronic package modules of FIG. 18;

FIG. 20 is a plan schematic view of two of the electronic package modules of FIGS. 18 and 19 after both modules have been separated from the strip and from each other;

FIG. 21 is a plan schematic view of various different geometric configurations of alternative open-ended preformed walls for an electromagnetic interference shield arrangement;

FIG. 22 is a plan schematic view of a geometric configuration of a continuous preformed wall for an electromagnetic interference shield arrangement;

FIG. 23 is a flow chart illustrating an exemplary method of providing intra-module electromagnetic interference shielding to at least one of a plurality of electronic package modules;

FIG. 24 shows one or more electronic package modules mounted on a wireless phone board that can include one or more features described herein;

FIG. 25 schematically depicts the wireless phone board with an electronic package module according to the present disclosure installed thereon; and

FIG. 26 schematically depicts a wireless device incorporating the wireless phone board of FIG. 25 with the electronic package module installed thereon.

### DETAILED DESCRIPTION

Aspects and embodiments described herein are directed to a method of providing intra-module electromagnetic interference shielding to at least one of a plurality of electronic package modules. Aspects and embodiments described herein are also directed to a strip of electronic package modules. Aspects and embodiments described herein provide an electronic package module in which intra-module electromagnetic interference shielding is disposed on a surface of an electronic package module and extends to a peripheral edge of the module. Aspects and embodiments described herein are also directed to an electronic device including an electronic package module resulting from the method described herein.

It is to be appreciated that embodiments of the package modules, devices, and methods discussed herein are not limited in application to the details of construction and the arrangement of components set forth in the following description or illustrated in the accompanying drawings. The package modules, devices, and methods are capable of implementation in other embodiments and of being practiced or of being carried out in various ways. Examples of specific implementations are provided herein for illustrative purposes only and are not intended to be limiting. Also, the phraseology and terminology used herein are for the purpose of description and should not be regarded as limiting. The use herein of “including”, “comprising”, “having”, “containing”, “involving”, and variations thereof is meant to encompass the items listed thereafter and equivalents thereof as well as additional items. References to “or” may be construed as inclusive so that any terms described using “or” may indicate any of a single, more than one, and all of the described terms.

In this disclosure, the term “shield wall” may refer to the wall structure that provides electromagnetic interference shielding. The shield wall may be referred to in this specification as a “preformed wall” to indicate that the shield wall can be formed prior to providing the electromagnetic interference shielding arrangement on the strip. However, the use of the term “preformed wall” in the specification is descriptive and does not limit the shield wall to any particular temporal sequence of formation relative to other manufacturing steps.

### Electronic Package Module of the Background Art

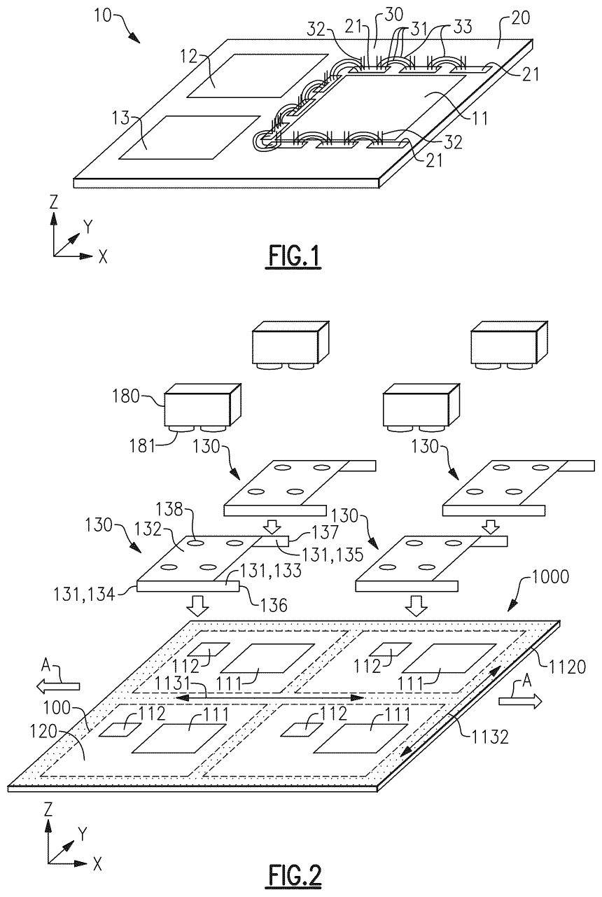

FIG. 1 shows a perspective schematic view of an electronic package module 10 of the background art. The electronic package module 10 has semiconductor components 11, 12, 13 mounted to an upper surface of a substrate panel 20. A wire shield or fence 30 is provided surrounding three sides of the semiconductor component 11. The wire shield or fence 30 is formed of a plurality of wire loops 31 and linear wire strands 32. The plurality of wire loops 31 are arranged in groups 33 of the wire loops. Metallic contact pads 21 are provided on the upper surface of the substrate panel 20 and surround the semiconductor component 11. The opposed ends of the wire loops 31 of each group 33 are attached to adjacent contact pads 21. Similarly, one end of each of the linear wire strands 32 is attached to a respective contact pad 21, with the strands 32 extending generally perpendicular to and away from the substrate panel 20. The wire shield or fence 30 serves an intra-module electromagnetic interference shield for the electronic package module 10. More specifically, the wire shield or fence 30 is provided to inhibit electromagnetic radiation emissions from the semiconductor component 11 from interfering with other components of the module 10 (for example, semiconductor components 12, 13) or devices external to the module 10. The wire shield or fence 30 also serves to inhibit electromagnetic radiation emissions from components (for example, semiconductor components 12, 13) of the electronic package module 10 or sources external to the module 10 from interfering with the operation of the semiconductor component 11. Although not shown in FIG. 1, a conformal electromagnetic shield would be applied over the electronic package module 10, with the upper ends of the linear wire strands 32 and the tallest of the wire loops 31 in surface contact with the conformal electromagnetic shield. The wire shield or fence 30 does not extend to the peripheral edge of the electronic package module 10, thereby resulting in a lessening of the electromagnetic interference shielding provided by the wire shield or fence 30. It will also be appreciated that the process of attaching the wire loops 31 and wire strands 32 to the metallic contact pads 21 requires precise alignment between the ends of the wires and the metallic contact pads.

### Strip of Electronic Package Modules and Features Thereof, and Related Method for Manufacture and Features Thereof, According to Aspects of the Present Disclosure

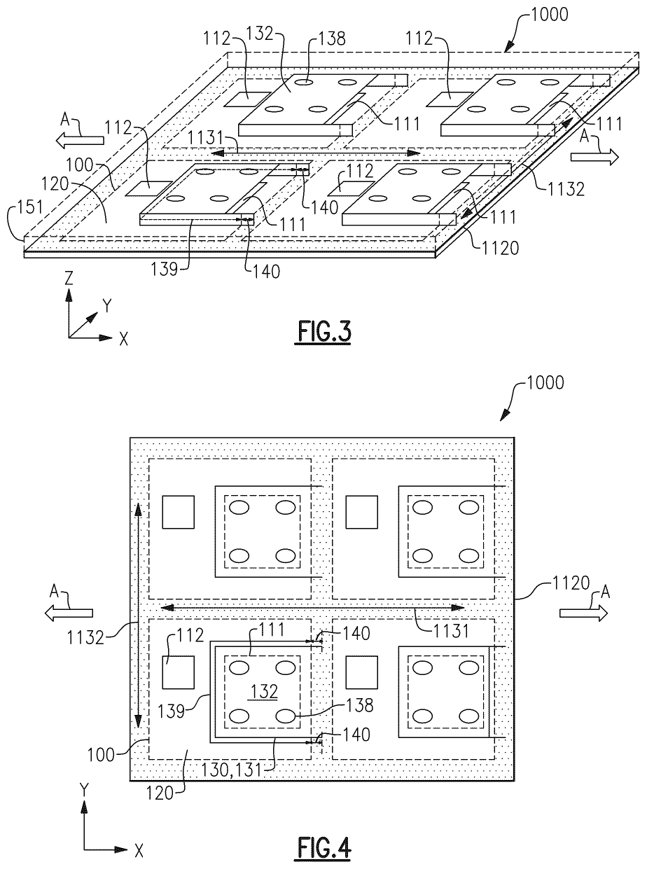

FIG. 2 is a perspective schematic view of a strip 1000 of electronic package modules 100 according to an embodiment of the present disclosure. FIG. 2 shows four distinct electronic package modules 100 of the strip 1000, with the perimeter of each module 100 shown in broken outline. However, arrows ‘A’ indicate how the strip 1000 may extend in size to include additional electronic package modules to those shown. For this embodiment, each of the electronic package modules 100 of the strip 1000 are identical to each other in structure and configuration. However, it will be appreciated that in other embodiments there may be some differences between distinct ones of the electronic package modules 100, such as in the type and configuration of semiconductor components forming part of different ones of the package modules 100.

The strip 1000 has a common substrate panel 1120 which is substantially planar and extends in X and Y directions to the periphery of the strip 1000. The common substrate panel 1120 includes distinct substrate panels 120 axially spaced apart from each other. Each substrate panel 120 corresponds to a different one of the electronic package modules 100. The common substrate panel 1120 may have a laminate construction. The common substrate panel 1120 may include a ceramic substrate. The ceramic substrate may include a low-temperature co-fired ceramic substrate. However, it will be appreciated that other materials may be used to form the common substrate panel 1120. The common substrate panel 1120 and each of the distinct substrate panels 120 may define a printed circuit board. Each of the electronic package modules 100 of the strip 1000 are spaced apart from each other by linear channels 1131 extending in the X direction and linear channels 1132 extending in the Y direction. Each of the linear channels 1131, 1132 defines a saw street, representing those regions of the strip 1000 which are intended to be cut through and discarded in order to separate each of the electronic package modules 100 from the strip 1000. Semiconductor components 111, 112 are mounted to the upper surface of each of the distinct substrate panels 120 of the electronic package modules 100. The semiconductor components 111, 112 may be in the form of a semiconductor die or any other desired semiconductor component. It will be appreciated that in other embodiments, the number and relative positioning of the semiconductor components may differ from that illustrated for this embodiment.

FIG. 2 also shows the provision of four distinct intra-module electromagnetic interference shield arrangements 130 for this first embodiment of the present disclosure. One shield arrangement 130 is provided for each of the electronic package modules 100 of the strip 1000. Each shield arrangement 130 has an electromagnetic interference shield wall (e.g., a preformed wall 131) and a roof structure 132. The shield arrangements 130 illustrated in FIG. 2 are identical to each other in terms of materials and geometry. Each shield arrangement 130 is formed of an electrically-conductive material, such as copper. However, it will be appreciated that other electrically-conductive materials may be used for the shield arrangements 130. Each of the preformed walls 131 shown in FIG. 2 has three sides 133, 134, 135 and defines an open-ended path, terminating in opposed free ends 136, 137. Each side 133, 134, 135 of the preformed wall 131 is shown aligned substantially perpendicular to a neighboring side of the wall. The roof structure 132 is coupled to an upper edge of each of the three sides 133, 134, 135 of the preformed wall 131. The roof structure 132 increases structural stiffness and stability of the shield arrangement 130 to help ensure that the three sides 133, 134, 135 of the preformed wall 131 are maintained in stable relative alignment. The roof structure 132 is generally planar. The roof structure 132 is provided with a plurality of apertures or slits 138 extending through the thickness of the roof structure. Although not shown in FIG. 2, similar apertures or slits may be provided extending through the preformed wall 131 in addition to or as an alternative to the apertures or slits 138 defined in the roof structure 132. As described in subsequent paragraphs, where a mold material is desired to be applied to the upper surface of the common substrate panel 1120, the provision of apertures or slits 138 in the roof structure 132 and/or similar features in the preformed wall 131 may help to facilitate the flow of the mold material across the surface of the common substrate panel 1120. As will be appreciated from FIGS. 2, 3, and 4, the preformed wall 131 of the shield arrangement 130 is formed with a size sufficient to allow the preformed wall to fit around three sides of the outside of semiconductor component 111.

During manufacture, each one of the shield arrangements 130 is mounted on the upper surface of the substrate panel 120 for each of the electronic package modules 100. In the embodiment illustrated in FIG. 2, a lifting assembly 180 with a plurality of suction cups 181 is used to engage with, move, and position the shield arrangements 130 to a desired position on the substrate panel 120 for respective ones of the electronic package modules 100. The suction cups 181 engage with the planar surface of the roof structure 132 of each shield arrangement 130. Suction applied via the suction cups 181 maintains a connection between the lifting assembly 180 and the roof structure 132. It will be appreciated that in other embodiments, other forms of lifting assembly may be used to engage with and move the shield arrangements 130 individually or collectively to a desired position on the substrate panels 120 of the package modules 100.

Although the shield arrangements 130 are illustrated as being spatially separate and distinct from each other in FIG. 2, in other embodiments, different ones of the shield arrangements may be physically connected to each other and moved together as a collective entity over the surface of the common substrate panel 1120 of the strip 1000.

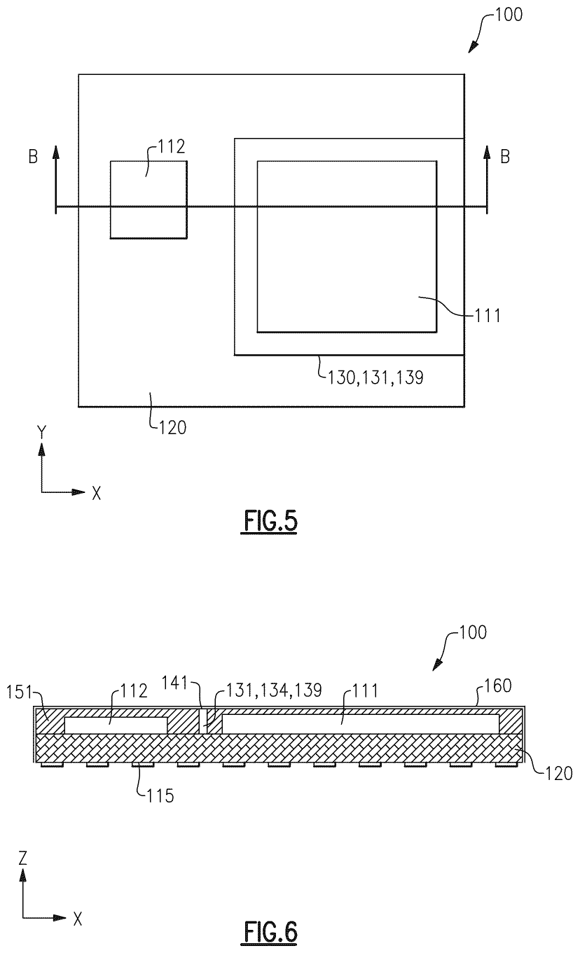

FIG. 3 shows each of the shield arrangements 130 in position on a substrate panel 120 of an electronic package module 100. The preformed wall 131 of each shield arrangement 130 is mounted on the upper surface of the respective substrate panel 120 to surround three sides of the semiconductor component 111. As shown in FIGS. 3 and 4, a central or inner portion 139 of each preformed wall 131 is located within the perimeter of a corresponding one of the electronic package modules 100, with outer portions 140 of each preformed wall 131 located outside the perimeter of the electronic package module 100. For the example illustrated in FIGS. 3 and 4, the outer portions 140 of each preformed wall 131 are located wholly within one of the channels or saw streets 1132. The three-sided configuration of the preformed wall 131 of each shield arrangement 130 ensures that the preformed wall is structurally stable and self-supporting on the surface of the strip 1000. In other words, the preformed wall 131 can maintain its geometric configuration and upright orientation on the strip surface without external support during handling and processing. However, each preformed wall 131 may also be secured to the surface of the substrate panel 120 of the respective electronic package module 100. By way of example, solder may be used to secure the preformed wall 131 to the surface of the substrate panel 120 at one or more distinct locations, for example, to metallic contact pads arranged on the surface of the substrate panel 120. However, other conventional means (such as any form of surface-mount technology (SMT)) may be used to couple the preformed wall 131 to the surface of the substrate panel 120.

As indicated previously, a mold structure 151 may be applied over the upper surface of the strip 1000 to at least partially encapsulate the semiconductor components 111, 112 and the shield arrangements 130 mounted to the strip. The mold structure 151 is shown in broken outline in FIG. 3. The apertures or slits 138 defined in the roof structure 132 of the shield arrangements 130 and/or similar features defined in the preformed wall 131 of the shield arrangements allow the flow of mold material therethrough to ensure that the space between the roof structure 132 and the substrate panel 120 may be filled with the mold material. The mold structure 151 may help to provide a level of physical protection to the semiconductor components 111, 112 and the preformed walls 131 of the shield arrangements 130 for each of the electronic package modules 100. Further, the mold structure 151 may also help to ensure that the preformed wall 131 of the shield arrangement 130 is maintained in stable alignment relative to the semiconductor component 111. An epoxy material may be used for the mold structure 151, although it will be appreciated that in alternative embodiments, other materials may be used for the mold structure that provide similar levels of physical protection to the semiconductor components 111, 112.

The mold structure 151 may be applied such that the respective roof structures 132 of the different shield arrangements 130 are embedded beneath the surface of the mold structure. A grinding, laser ablation, or similar operation may be performed to progressively remove excess mold material of the mold structure 151 to a desired height above the surface of the common substrate panel 1120. In one embodiment, the grinding, laser ablation, or similar operation may be performed to remove the roof structure 132 of the shield arrangements 130, leaving an edge of the preformed wall 131 exposed through the mold structure 151. Alternatively, the grinding, laser ablation, or similar operation may instead be performed to expose and retain the roof structure 132 of the shield arrangements 130. In some embodiments, the mold material may instead be applied to leave a portion of the shield arrangement 130 protruding from the mold structure 151, with a grinding, laser ablation, or similar operation performed on the protruding portion of the shield arrangement to cut or grind the shield arrangement so as to be flush or level with the surface of the mold structure 151.

Returning to FIGS. 3 and 4, each of the electronic package modules 100 may be separated from the strip 1000 by a cutting tool acting on each of the channels or saw streets 1131, 1132. Operation of the cutting tool removes the strip material in the channels or saw streets 1131, 1132, thereby removing the outer portions 140 of the preformed wall 131, in addition to material of the common substrate panel 1120 and mold structure 151 located in the channels or saw streets 1131, 1132.

FIG. 5 shows a plan schematic representation of a distinct one of the electronic package modules 100 after separation from the strip 1000. As can be seen, free ends of the remaining central or inner portion 139 of the preformed wall 131 of the shield arrangement 130 extend to the peripheral edge of one of the sides of the electronic package module 100. The electronic package module 100 of FIG. 5 is one in which the roof structure 132 has been removed from the shield arrangement 130; for example, by use of a grinding or similar operation, as previously described. For convenience, the mold structure 151 is excluded from FIG. 5. As described herein, the electromagnetic interference shielding arrangement (or shield arrangement 130) includes the preformed wall 131 and the roof structure 132, and encompasses both the inner portions 139 that are located within the perimeter of the electronic package module 100 and the outer portions 140 that are located outside the perimeter and are removed during singulation. After singulation removes the outer portions 140, the remaining portions of the electromagnetic interference shielding arrangement that stay with the separated electronic package module 100 form an intra-module electromagnetic interference shielding structure. The intra-module electromagnetic interference shielding structure can include the remaining inner portions 139 of the preformed wall 131 alone (as shown in FIG. 5, where the roof structure 132 has been removed), or can include both the remaining inner portions 139 of the preformed wall 131 and the roof structure 132 (in embodiments where the roof structure 132 is retained). The intra-module electromagnetic interference shielding structure provides the intra-module electromagnetic interference shield for the separated electronic package module 100.

Various singulation processes can be used as the cutting tool to separate the electronic package modules 100 from the strip 1000, each of which imparts characteristic physical features to the edges of the preformed wall 131 where the outer portions 140 are removed. In embodiments where a mechanical dicing saw is used as the cutting tool, the separated edges of the preformed wall 131 (e.g., the edges where the outer portions 140 were removed) can exhibit saw marks, striations, or micro-scratches oriented substantially parallel to the direction of blade travel. The cut surface can have a roughness profile characteristic of mechanical sawing, with surface roughness values typically in the range of 0.5 to 5 micrometers Ra. In embodiments where laser singulation is used as the cutting tool, the separated edges of the preformed wall 131 typically exhibit heat-affected zones, discoloration, or re-solidified material characteristic of laser ablation or melting. The cut surface can show evidence of thermal processing, such as oxidation layers, micro-cracks from thermal stress, or a glazed appearance from re-solidified metal. In embodiments where plasma dicing is used as the cutting tool, the separated edges of the preformed wall 131 can exhibit a chemically etched appearance with relatively smooth surfaces but with micro-roughness characteristic of plasma etching processes. In embodiments where stealth dicing (laser-induced internal modification followed by mechanical separation) is used as the cutting tool, the separated edges of the preformed wall 131 can exhibit a combination of laser-modified regions and mechanically fractured surfaces. Regardless of the singulation method used, the separated edges of the preformed wall 131 where the outer portions 140 were removed exhibit physical characteristics that distinguish them from edges that were formed prior to placement of the shield arrangement 130 on the strip 1000, such as edges formed by stamping, etching, or molding the preformed wall 131 to its final shape before positioning on the strip 1000. These singulation-induced edge characteristics provide physical evidence that the preformed wall 131 was positioned across module boundaries and subsequently separated during the singulation process, rather than being applied to individual electronic package modules 100 after singulation. A person having ordinary skill in the art of semiconductor packaging would be able to determine, by inspecting the physical structure of the edge of the intra-module electromagnetic interference shield, that the intra-module electromagnetic interference shield has been made by providing the shield arrangement 130 on the strip 1000 of electronic package modules 100 and singulating the first electronic package module 110 from the strip 1000, based on the presence of the singulation-induced edge characteristics described above.

In the separated electronic package module 100 shown in FIG. 5, the intra-module electromagnetic interference shielding structure is at least partially positioned between the first semiconductor component 111 and the second semiconductor component 112, providing electromagnetic interference shielding for the first semiconductor component 111. Because the singulation cutting tool cuts through both the strip material (substrate panel 1120) and the outer portions 140 of the preformed wall 131 in the same operation, the wall edges of the intra-module electromagnetic interference shielding structure (i.e., the edges where the outer portions 140 were removed) are substantially aligned with the side edges (peripheral edges) of the substrate panel 120 of the separated electronic package module 100. This edge alignment occurs because the cutting tool creates both the substrate edge and the wall edge simultaneously at substantially the same location. A pre-formed shield applied to an individual module after singulation would typically be positioned inward from the peripheral edges of the substrate rather than aligned with those edges, and would have edges formed by stamping, etching, or molding processes rather than by singulation cutting. Thus, the combination of edge alignment and singulation-induced edge characteristics provides structural evidence distinguishing the intra-module electromagnetic interference shielding structure from shields applied after singulation.

FIG. 6 shows a schematic cross-sectional view through section B-B of the electronic package module 100 of FIG. 5. FIG. 6 illustrates a single-sided, land-grid array variant of the electronic package module 100. A land grid array 115 is defined on the lower surface of the substrate panel 120 to enable connection of the electronic package module 100 to a separate circuit board. FIG. 6 shows the side 134 of the preformed wall 131 located between semiconductor components 111 and 112. The mold structure 151 is shown encapsulating the entirety of semiconductor components 111, 112. The electronic package module 100 of FIG. 6 is one in which the roof structure 132 of the shield arrangement 130 has been removed to leave an upper face 141 of the preformed wall 131 exposed through and flush with the upper surface of the mold structure 151. A conformal electromagnetic shield 160 is arranged over the upper and side surfaces of the electronic package module 100 and is in surface contact with the exposed upper face 141 of the preformed wall 131 of the shield arrangement 130. The conformal electromagnetic shield 160 may be formed of copper or another suitable electrically conductive material.

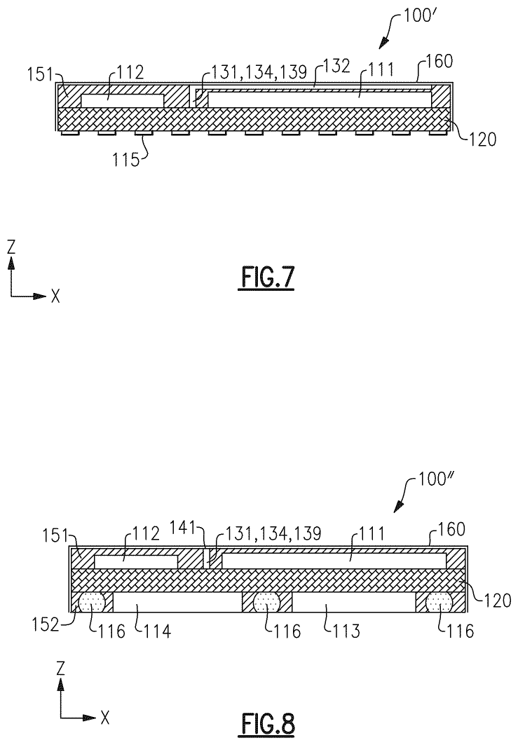

FIG. 7 shows a schematic cross-sectional view through section B-B of FIG. 5 for an electronic package module 100′, being a variant of the electronic package module 100 of FIG. 6. The electronic package module 100′ differs from the module 100 of FIG. 6 in that the roof structure 132 of the shield arrangement 130 is retained. Further, the conformal electromagnetic shield 160 is arranged over the upper and side surfaces of the electronic package module 100′ to be in surface contact with the roof structure 132 of the shield arrangement 130.

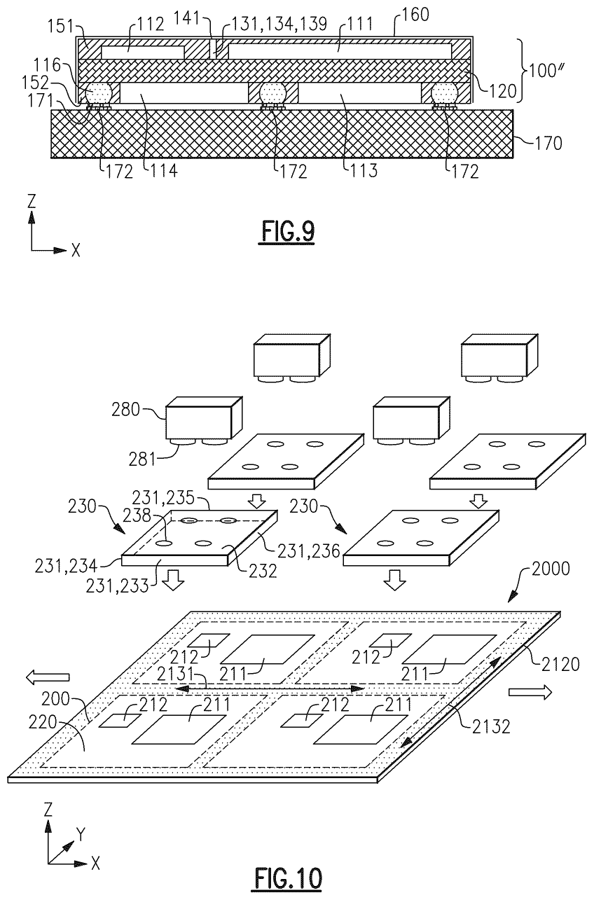

FIG. 8 shows a schematic cross-sectional view through section B-B of FIG. 5 for an electronic package module 100″, being a variant of the electronic package modules 100, 100′ of FIGS. 6 and 7. The electronic package module 100″ differs from the modules 100, 100′ in that the package module 100″ is a dual-sided molded ball grid array variant of an electronic package module. Semiconductor components 113, 114 are shown mounted on the lower surface of the substrate panel 120 of the electronic package module 100″. A mold structure 152 is provided on the lower surface of the substrate panel 120, with the semiconductor components 113, 114 exposed through the mold structure. A ball grid array of solder balls 116 is provided on the lower surface of the substrate panel 120 to enable connection of the electronic package module 100″ to a separate circuit board. It will be appreciated that the semiconductor components 113, 114 and ball grid array of solder balls 116 are preferably mounted to the lower surface of the substrate panels 120 of the strip 1000 before the respective electronic package modules 100″ are separated from the strip 1000. In common with the electronic package module 100 of FIG. 6, the electronic package module 100″ is one in which the roof structure 132 of the shield arrangement 130 has been removed to leave an upper face 141 of the preformed wall 131 exposed through and flush with the upper surface of the mold structure 151. A conformal electromagnetic shield 160 is arranged over the upper and side surfaces of the electronic package module 100″ and is in surface contact with the exposed upper face 141 of the preformed wall 131 of the shield arrangement 130.

FIG. 9 is a schematic view showing the electronic package module 100″ of FIG. 8 mounted to a surface of a separate circuit board 170 to form an electronic sub-assembly. Exposed surfaces of the array of solder balls 116 permit the electronic package module 100″ to be coupled to the circuit board 170. More specifically, intermediate portions of solder 171 are provided between exposed surfaces of the solder balls 116 and corresponding contact pads 172 provided on the surface of the circuit board 170.

It will be appreciated that the concept may be applied to the manufacture of various different forms of single-sided and dual-sided electronic package modules, without being limited to the embodiments illustrated in the figures.

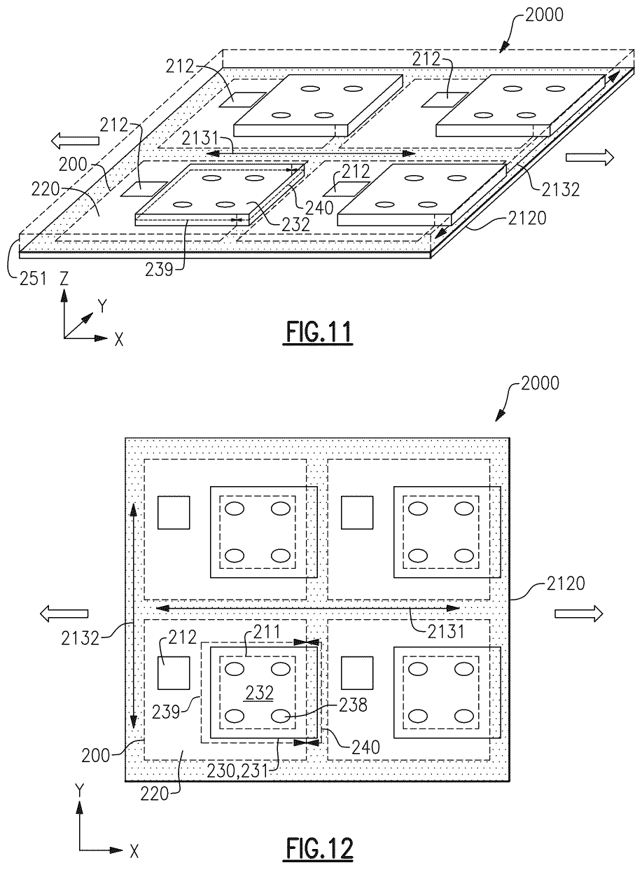

FIG. 10 is a perspective schematic view of a strip 2000 of electronic package modules 200 according to a further embodiment of the present disclosure. In a similar manner to FIG. 2, FIG. 10 shows four distinct electronic package modules 200 of the strip 2000, but arrows indicate how the strip may extend in size to include additional electronic package modules. The strip 2000 has a common substrate panel 2120 which is substantially planar and extends in X and Y directions to the periphery of the strip 2000. The common substrate panel 2120 defines distinct substrate panels 220 axially spaced apart from each other. Each substrate panel 220 corresponds to a different one of the electronic package modules 200. The common substrate panel 2120 may have the same construction and be formed from the same materials as the common substrate panel 1120 of FIG. 2. Each of the electronic package modules 200 of the strip 2000 are spaced apart from each other by linear channels 2131 extending in the X direction and linear channels 2132 extending in the Y direction. The linear channels 2131, 2132 define saw streets which are sacrificed during the process of separating the electronic modules 200 from the strip 2000. Semiconductor components 211, 212 are mounted to the upper surface of each of the distinct substrate panels 220 of the electronic package modules 200 in the same manner indicated for the embodiment of FIG. 2.

Where the embodiment of FIG. 10 differs from the embodiment of FIG. 2 is in the configuration of the intra-module electromagnetic interference shield arrangements 230 provided for each of the electronic package modules 200. Each of the shield arrangements 230 in FIG. 10 has a preformed wall 231 defining a closed, continuous path formed of four sides 233, 234, 235, 236. Each side 233, 234, 235, 236 of the preformed wall 231 is shown aligned substantially perpendicular to neighboring sides of the wall. Each shield arrangement 230 also has a roof structure 232 coupled to an upper edge of each of the four sides 233, 234, 235, 236 of the preformed wall 231. Apertures or slits 238 are defined in the roof structure 232; similar apertures or slits may also be formed through the sides of the preformed wall 231.

During manufacture, each of the shield arrangements 230 is mounted on the upper surface of the substrate panel 220 for each of the electronic package modules 200 so that the preformed wall 231 surrounds four sides of the semiconductor component 211. A suction-based lifting assembly 280 may be employed to engage, move, and position the shield arrangements 230 to a desired position on the substrate panel 220 for respective ones of the modules 200, in a similar manner to the lifting assembly 180 of the embodiment of FIG. 2. As shown in FIGS. 11 and 12, a central or inner portion 239 of each preformed wall 231 locates within the perimeter of a corresponding one of the electronic package modules 200, with an outer portion 240 of the preformed wall 231 located outside the perimeter of the electronic package module 200. For the example illustrated in FIGS. 11 and 12, the outer portion 240 of each preformed wall 231 is located wholly within the linear channels or saw streets 2132. Each preformed wall 231 may be secured to the surface of the substrate panel 220 of the respective electronic package module 200 in the same manner as described for the preformed wall 131 of the embodiment of FIGS. 2 to 5.

A mold structure 251 may be applied over the upper surface of the strip 2000 to at least partially encapsulate the semiconductor components 211, 212 and the shield arrangements 230 mounted to the strip in the same manner described for the embodiment of FIGS. 2 to 5. The mold structure 251 may be formed of the same materials as described for the mold structure 151. The mold structure 251 is shown in broken outline in FIG. 11.

Returning to FIGS. 11 and 12, each of the electronic package modules 200 is separated from the strip 2000 by a cutting tool acting on each of the channels or saw streets 2131, 2132, in the same manner as for the embodiment of FIGS. 2 to 5. Operation of the cutting tool removes the strip material of the channels or saw streets 2131, 2132, thereby removing the outer portion 240 of the preformed wall 231 in addition to material of the common substrate panel 2120 and mold structures 251 located in the channels or saw streets 2131, 2132.

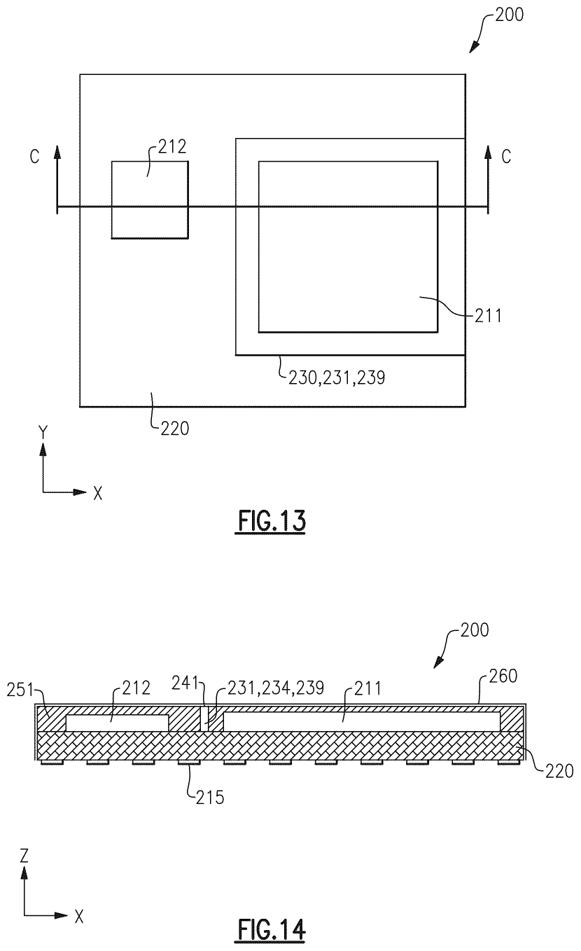

FIG. 13 shows a plan schematic representation of a distinct one of the electronic package modules 200 after being separated from the strip 2000. As can be seen, free ends of the remaining central or inner portion 239 of the preformed wall 231 of the shield arrangement 230 extend to the peripheral edge of one of the sides of the electronic package module 200. The electronic package module 200 of FIG. 13 is one in which the roof structure 232 has been removed from the shield arrangement 230, for example by use of a grinding or similar operation as previously described for the embodiment of FIGS. 2 to 5. For convenience, the mold structure 251 is excluded from FIG. 13.

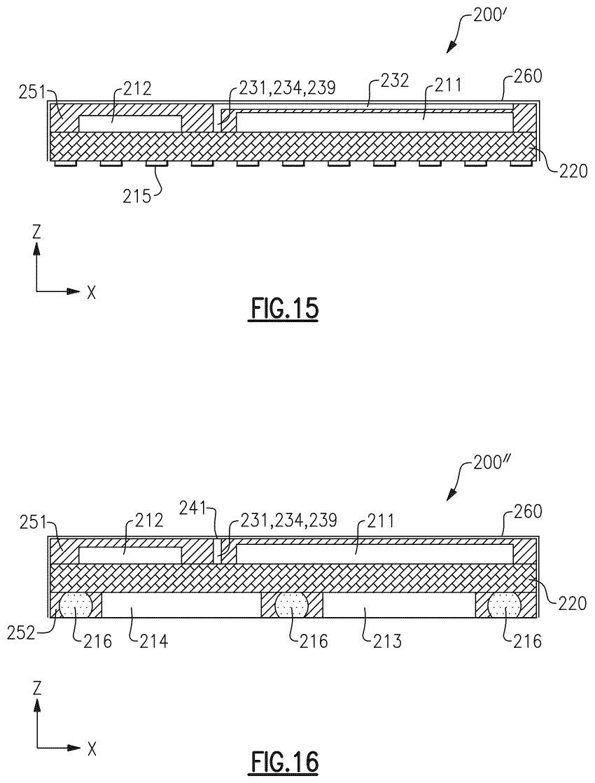

FIG. 14 shows a schematic cross-sectional view through section C-C of the electronic package module 200 of FIG. 13. The resulting electronic package module 200 corresponds in configuration and structure to the single-sided land grid array variant of electronic package module 100 of FIG. 6, with a land grid array 215 defined on the lower surface of the substrate panel 220 to enable connection of the electronic package module 200 to a separate circuit board. A conformal electromagnetic shield 260 is arranged over the upper and side surfaces of the electronic package module 200 and is in surface contact with an exposed upper face 241 of the preformed wall 231 of the shield arrangement 230, with the roof structure 232 having been removed in an earlier operation.

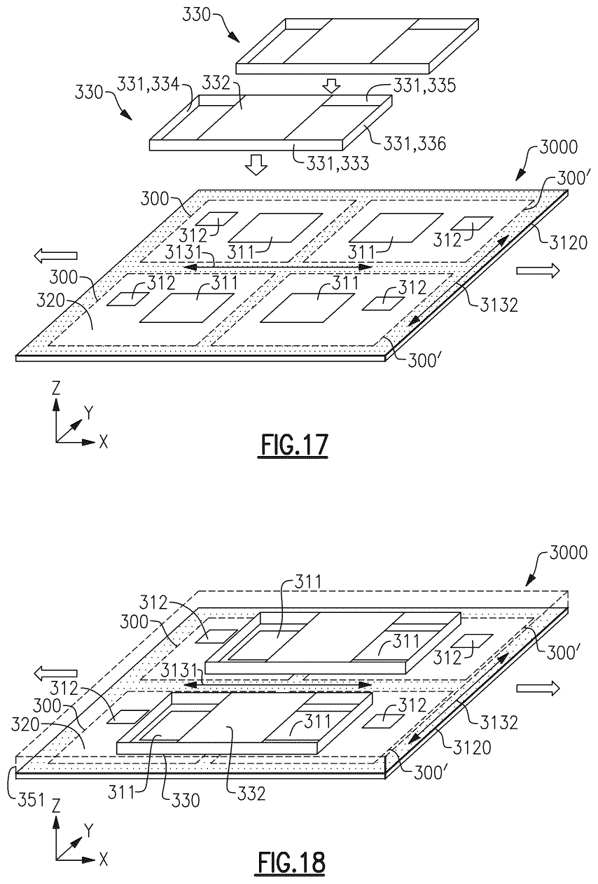

FIG. 15 shows a schematic cross-sectional view through section C-C of FIG. 13 for an electronic package module 200′, being a variant of the electronic package module 200 of FIG. 14. The electronic package module 200′ differs from the module 200 of FIG. 14 in that the roof structure 232 of the shield arrangement 230 is retained. Further, the conformal electromagnetic shield 260 is arranged over the upper and side surfaces of the electronic package module 200 to be in surface contact with the roof structure 232 of the shield arrangement 230, in a similar manner to the electronic package module 100′ of FIG. 7.

FIG. 16 shows a schematic cross-sectional view through section C-C of FIG. 13 for an electronic package module 200″, being a variant of the electronic package modules 200, 200′ of FIGS. 14 and 15. The resulting electronic package 200″ corresponds in configuration and structure to the dual-sided molded ball grid array variant of electronic package module 100″ of FIG. 8. Semiconductor components 213, 214 are shown mounted on the lower surface of the substrate panel 220 of the electronic package module 200, with a ball grid array of solder balls 216 provided on the lower surface of the substrate panel 220. A mold structure 252 is provided on the lower surface of the substrate panel 220, with the semiconductor components 213, 214 exposed through the mold structure.

The electronic package modules 200, 200′, 200″ may be mounted to a surface of a separate circuit board to form an electronic sub-assembly. For example, the electronic package module 200″ of FIG. 16 may be mounted to a surface of a circuit board in the same manner as described for the embodiment of FIG. 9.

FIG. 17 is a perspective schematic view of a strip 3000 of electronic package modules 300, 300′ according to a further embodiment of the present disclosure. In a similar manner to FIG. 10, FIG. 17 shows four distinct electronic package modules 300, 300′ of the strip 3000, but arrows indicate how the strip may extend in size to include additional electronic package modules. As can be seen from FIG. 17, the electronic package modules 300′ are mirror images of electronic package modules 300, comprising the same components but in a mirror image configuration to each other. The strip 3000 has a common substrate panel 3120 which is substantially planar and extends in X and Y directions to the periphery of the strip 3000. The common substrate panel 3120 defines distinct substrate panels 320 axially spaced apart from each other. Each substrate panel 320 corresponds to a different one of the electronic package modules 300, 300′. The common substrate panel 3120 may have the same construction and be formed from the same materials as the common substrate panel 2120 of FIG. 10. Linear channels 3131 extend in the X direction and linear channels 3132 extend in the Y direction to separate adjacent ones of the modules 300, 300′ from each other. As for the previously described embodiments, the linear channels 3131, 3132 define saw streets which are sacrificed during the process of separating the electronic modules 300, 300′ from the strip 3000. Semiconductor components 311, 312 are mounted to the upper surface of each of the distinct substrate panels 320 of the electronic package modules 300, 300′ in the same manner indicated for the embodiment of FIG. 2.

Where this embodiment differs from the embodiment of FIGS. 10 to 13 is in the configuration of the intra-module electromagnetic interference shield arrangements 330 and the positioning of the preformed wall 331 of the shield arrangements 330 on the strip 3000. Each of the shield arrangements 330 in FIG. 17 has a preformed wall 331 defining a closed, continuous path formed of four sides 333, 334, 335, 336. Each shield arrangement 330 also has a roof structure 332 coupled to an upper edge of opposed sides 333, 335 of the preformed wall 331. The preformed wall 331 of shield arrangement 330 encloses a larger area than the preformed wall 231 of shield arrangement 230 of FIG. 10.

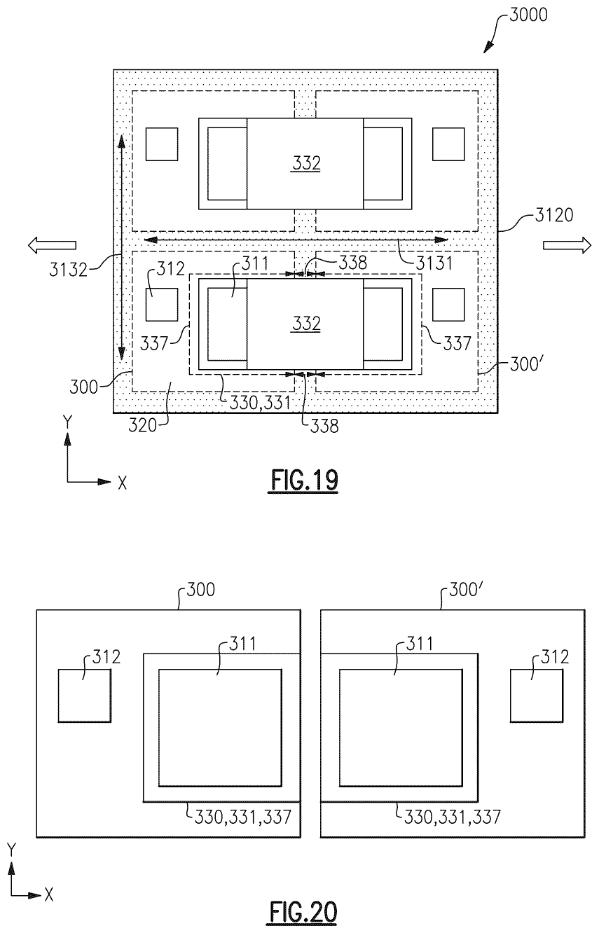

During manufacture, each of the shield arrangements 330 is mounted on the upper surface of the strip 3000 so that the preformed wall 331 encloses the semiconductor components 311 of both electronic package module 300 and adjacent electronic package module 300′. Each preformed wall 331 therefore spans the linear channel 3132 defining the saw street between electronic module 300 and electronic module 300′. As shown in FIG. 19, an inner portion 337 of each preformed wall 331 locates within the perimeter of each one of adjacent electronic package modules 300, 300′, with outer portions 338 of each preformed wall 331 locating outside the perimeter of the electronic package modules 300, 300′ within the saw street 3132. Each preformed wall 331 may be secured to the surface of the substrate panel 320 of the respective electronic package modules 300, 300′ in the same manner as described for the preformed wall 131 of the embodiment of FIGS. 2 to 5.

A mold structure 351 may be applied over the upper surface of the strip 3000 to at least partially encapsulate the semiconductor components 311, 312 and the shield arrangements 330 mounted to the strip in the same manner described for the embodiment of FIGS. 2 to 5. The mold structures 351 may be formed of the same materials as described for the mold structure 151. The mold structure 351 is shown in broken outline in FIG. 18.

Returning to FIG. 19, each of the electronic package modules 300, 300′ are separated from the strip 3000 by a cutting tool acting on each of the channels or saw streets 3131, 3132, in the same manner as described for the first embodiment of the present disclosure. Operation of the cutting tool removes the strip material of the channels or saw streets 3131, 3132, thereby removing the outer portions 338 of the preformed wall 331 in addition to material of the common substrate panel 3120 and mold structure 351 located in the channels or saw streets 3131, 3132.

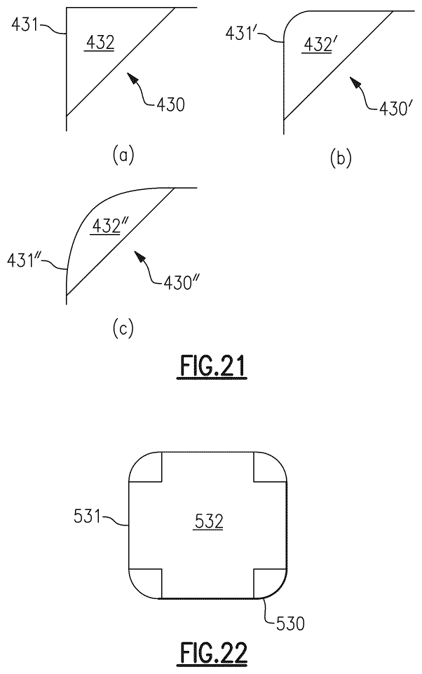

FIG. 20 shows a plan schematic representation of adjacent electronic package modules 300, 300′ after being separated from the strip 3000. As can be seen, free ends of the remaining inner portion 337 of the preformed wall 331 extend to the peripheral edge of one of the sides of electronic package module 300 and one of the sides of electronic package module 300′. The electronic package module 300′ is a mirror image of electronic package module 300.

Both electronic package modules 300, 300′ may be mounted to a surface of a separate circuit board in a similar manner to that described for the electronic package modules 100, 100′, 100″, 200, 200′, 200″.

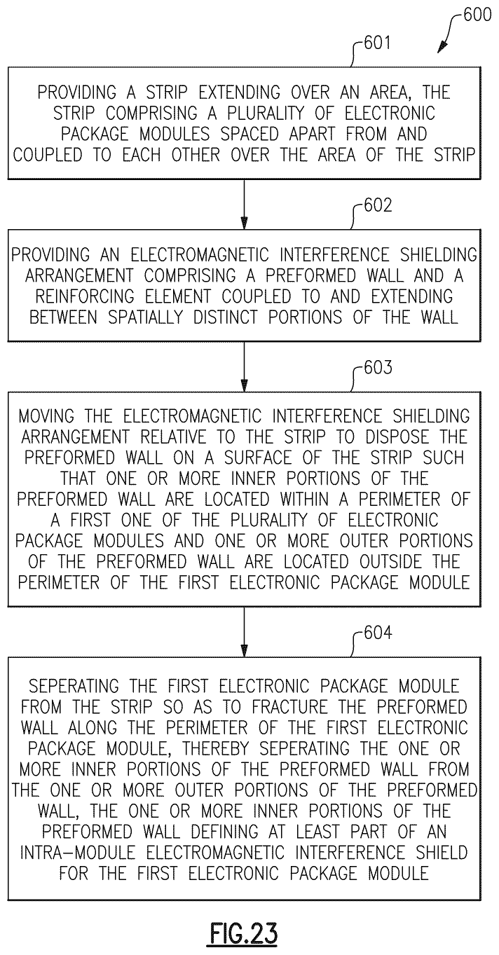

FIG. 21 illustrates three alternative configurations—(a), (b), and (c)—to the open-ended preformed wall 131 of the shield arrangement 130 illustrated in the embodiment of FIG. 2. Configuration (a) of FIG. 21 shows a plan view of a shield arrangement 430 having an open-ended preformed wall 431 with two linear sides connected to each other at a right-angled corner. A roof structure 432 is shown extending between the two sides of the preformed wall 431. Configuration (b) of FIG. 21 shows a plan view of a shield arrangement 430′ having an open-ended preformed wall 431′ with two linear sides coupled to each other with a curved portion. A roof structure 432′ is shown extending between the two sides of the preformed wall 431′. Configuration (c) of FIG. 21 shows a plan view of a shield arrangement 430″ having an open-ended preformed wall 431″ being continuously curved along the entirety of its length. A roof structure 432″ is shown extending between the opposite ends of the curved preformed wall 431″.

FIG. 22 illustrates an alternative configuration to the closed, continuous preformed wall 231 of the shield arrangement 230 illustrated in the embodiment of FIG. 10. FIG. 22 shows a shield arrangement 530 having a continuous preformed wall 531 with four linear sides, with adjacent pairs of the linear sides coupled to each other with a curved portion. A cruciform-shaped roof structure 532 is shown extending between opposed sides of the preformed wall 531.

It will be appreciated that the shape of the preformed wall that is used may be varied according to the profile and size of the semiconductor component(s) of the electronic package module which it is intended to enclose and/or be located between.

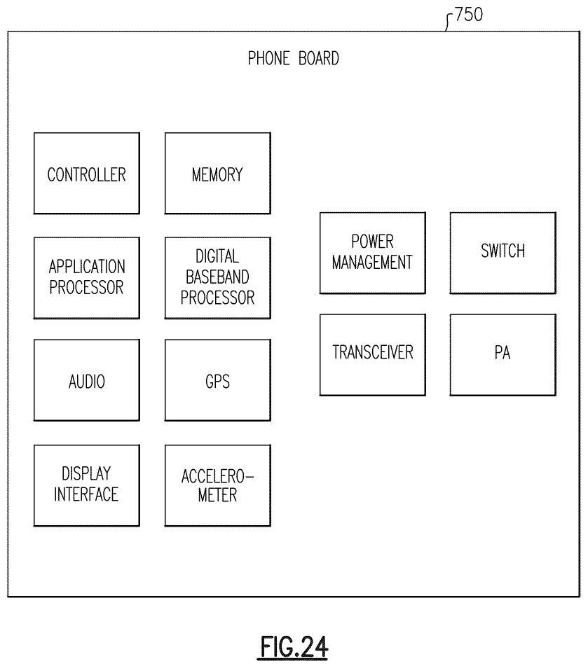

FIG. 23 is a flow chart illustrating an exemplary method 600 of manufacturing an electronic package according to aspects of the present disclosure. FIG. 23 summarizes the steps discussed above in the manufacture of electronic package modules 100, 100′, 100″, 200, 200′, 200″, 300, 300′. It therefore follows that the steps 601, 602, 603, 604 of the method 600 illustrated in FIG. 23 may be understood by reference to the preceding paragraphs of the present disclosure describing the structure and formation of electronic package modules 100, 100′, 100″, 200, 200′, 200″, 300, 300′ from strips 1000, 2000, 3000.

The method 600 has a step 601 of providing a strip extending over an area, the strip comprising a plurality of electronic package modules spaced apart from and coupled to each other over the area of the strip. By way of example, the strip and electronic package modules may be any of strips 1000, 2000, 3000 and electronic package modules 100, 100′, 100″, 200, 200′, 200″, 300, 300′ described above. While the steps of method 600 are described in a particular sequence, the order of certain steps can be modified, combined, or performed simultaneously where technically feasible without departing from the scope of the invention. Steps that are not technically dependent on one another can be performed in any suitable order.

The method 600 has a step 602 of providing an electromagnetic interference shielding arrangement comprising a preformed wall. The shielding arrangement may also include a reinforcing element coupled to and extending between spatially distinct portions of the preformed wall. By way of example, the shielding arrangement may be any of the shield arrangements 130, 230, 330 described above, and the preformed wall may be any of the preformed walls 131, 231, 331 described above. Where the shielding arrangement includes a reinforcing element, the reinforcing element may be in the form of a roof structure, such as any of the roof structures 132, 232, 332 of the shield arrangements 130, 230, 330 described above.

The method 600 also has a step 603 of moving the electromagnetic interference shielding arrangement relative to the strip to dispose the preformed wall on a surface of the strip such that one or more inner portions of the preformed wall are located within a perimeter of a first one of the plurality of electronic package modules and one or more outer portions of the preformed wall are located outside the perimeter of the first electronic package module. In some embodiments, the step of moving the electromagnetic interference shielding arrangement can be performed as part of the step of providing the electromagnetic interference shielding arrangement (step 602), such that providing the shielding arrangement includes positioning it on the strip surface in the desired configuration. By way of example, the one or more inner portions may be the inner portions 139, 239, 337 of the preformed walls 131, 231, 331 of shielding arrangements 130, 230, 330 and the one or more outer portions may be the outer portions 140, 240, 338 of the same preformed walls 131, 231, 331. The one or more inner portions of the preformed wall may at least partially surround a semiconductor component mounted on the surface of the first electronic package module. Although not shown in FIG. 23, the method 600 may also include a step of applying a mold material over the surface of the strip to define a mold structure. The mold structure may at least partially encapsulate the shielding arrangement and any semiconductor components mounted on the surface of the strip, in a similar manner to the mold structures 151, 251, 351 described above.

The method 600 also has a step 604 of separating the first electronic package module from the strip so as to fracture the preformed wall along the perimeter of the first electronic package module, thereby separating the one or more inner portions of the preformed wall from the one or more outer portions of the preformed wall, the one or more inner portions of the preformed wall defining at least part of an intra-module electromagnetic interference shield for the first electronic package module. By way of example, the resulting electronic package module may be in accordance with any of the electronic package modules 100, 100′, 100″, 200, 200′, 200″, 300, 300′ discussed above.

Although not shown in FIG. 23, the method may also include a step of applying a conformal shield over an exterior of the first electronic package module such that the conformal shield is in surface contact with the shielding arrangement. By way of example, the conformal shield may be in accordance with the conformal shield 160, 260 described above.

It will be appreciated that the method may be applied to any form of single-sided or dual-sided electronic package module.

### Exemplary Devices Incorporating Electronic Package Modules According to Aspects of the Present Disclosure

FIG. 24 shows an embodiment of a circuit board 750, such as a wireless phone board, which may include one or more package modules within the scope of the present disclosure, such as any of the package modules 100, 100′, 100″, 200, 200′, 200″, 300, 300′ described above. Non-limiting examples of package modules that can benefit from such packaging features as disclosed herein include, but are not limited to, a controller module, an application processor module, an audio module, a display interface module, a memory module, a digital baseband processor module, a global positioning system (GPS) module, an accelerometer module, a power management module, a transceiver module, a switching module, and a power amplifier module. So, each of the package modules depicted for the wireless phone board 750 of FIG. 24 may correspond to any of the electronic package modules 100, 100′, 100″, 200, 200′, 200″, 300, 300′.

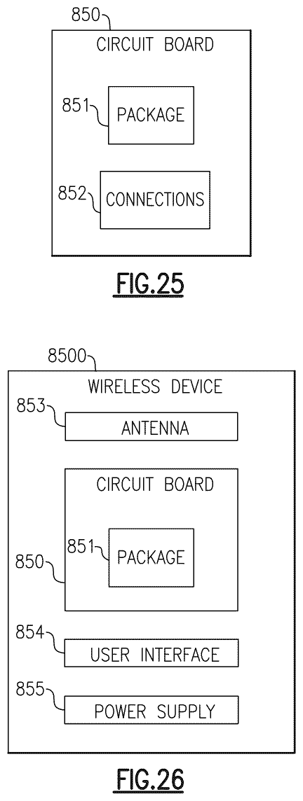

FIG. 25 schematically depicts a circuit board 850 having a package module 851 mounted thereon in the manner described herein; by way of example, the package module 851 may correspond to any of the package modules 100, 100′, 100″, 200, 200′, 200″, 300, 300′ described above. The circuit board 850 may also include other features, such as a plurality of connections 852 to facilitate operations of various packages mounted thereon. FIG. 26 schematically depicts a wireless device 8500 (for example, a cellular phone) having a circuit board 850 (for example, a phone board). The circuit board 850 is shown to include a package module 851 mounted thereon in the manner described herein; for example, the package module 851 may correspond to any of the molded package modules 100, 100′, 100″, 200, 200′, 200″, 300, 300′ described above. The wireless device 8500 is shown to further include other components, such as an antenna 853, a user interface 854, and a power supply 855.

It Will be noted that the figures are for illustrative purposes only, and are not to scale.

Having described above several aspects of at least one embodiment, it is to be appreciated that various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from the proper construction of the appended claims, and their equivalents.

1. A method of providing intra-module electromagnetic interference shielding, the method comprising:
providing a strip including a plurality of electronic package modules spaced apart from each other;
providing an electromagnetic interference shielding arrangement including a shield wall to dispose the shield wall on a surface of the strip such that an inner portion of the shield wall is located within a perimeter of a first module of the plurality of electronic package modules and an outer portion of the shield wall is located outside the perimeter of the first module; and
separating the first module from the strip so as to fracture the shield wall along the perimeter of the first module, thereby separating the inner portion of the shield wall from the outer portion of the shield wall, the inner portion of the shield wall defining at least part of an intra-module electromagnetic interference shield for the first module.

2. The method according to claim 1 wherein the electromagnetic interference shielding arrangement further includes a reinforcing element coupled to and extending between spatially distinct portions of the shield wall to enhance structural stiffness of the electromagnetic interference shielding arrangement, wherein providing the electromagnetic interference shielding arrangement includes engaging a lifting assembly with the reinforcing element to lift and translate the electromagnetic interference shielding arrangement.

3. The method according to claim 2 wherein providing the electromagnetic interference shielding arrangement further includes applying suction to the reinforcing element by the lifting assembly to hold the electromagnetic interference shielding arrangement, and wherein the reinforcing element includes a roof structure extending over the shield wall, wherein providing the electromagnetic interference shielding arrangement includes applying suction to the roof structure by the lifting assembly to hold the electromagnetic interference shielding arrangement.

4. The method according to claim 1 further comprising:
providing a second electromagnetic interference shielding arrangement for a second module of the plurality of electronic package modules, the second electromagnetic interference shielding arrangement includes a second shield wall, and wherein providing the second electromagnetic interference shielding arrangement includes moving the electromagnetic interference shielding arrangement to dispose the second shield wall such that an inner portion of the second shield wall is located within a perimeter of the second module and an outer portion of the second shield wall is located outside the perimeter of the second module; and
separating the second module from the strip so as to fracture the second shield wall along the perimeter of the second module, the inner portion of the second shield wall defining at least part of the intra-module electromagnetic interference shield for the second module.

5. The method according to claim 1 wherein providing the electromagnetic interference shielding arrangement is performed such that the outer portion of the shield wall extends over a saw street of the strip.

6. The method according to claim 5 wherein the saw street is disposed between the first module and an adjacent one or more of the plurality of electronic package modules.

7. The method according to claim 6 wherein providing the electromagnetic interference shielding arrangement is performed such that the outer portion of the shield wall is confined to the saw street.

8. The method according to claim 6 wherein providing the electromagnetic interference shielding arrangement is performed such that the outer portion of the shield wall extends beyond the saw street.

9. The method according to claim 1 wherein providing the electromagnetic interference shielding arrangement includes providing the shield wall to define a continuous path.

10. The method according to claim 1 wherein:
providing the electromagnetic interference shielding arrangement includes providing the shield wall to define an open-ended path extending between first and second free ends;
providing the electromagnetic interference shielding arrangement is performed such that one or both of the first and second free ends are located outside of the perimeter of the first module;
providing the electromagnetic interference shielding arrangement includes providing the shield wall as configured to be self-supporting when disposed on the surface of the strip; and
the shield wall includes first and second linear wall sections, the first and second linear wall sections being non-colinear relative to each other.

11. The method according to claim 1 further comprising applying a mold structure over the surface of the strip to at least partially embed the electromagnetic interference shielding arrangement in the mold structure.

12. The method according to claim 11 wherein applying the mold structure is performed such that the mold structure covers a roof structure of the electromagnetic interference shielding arrangement.

13. The method according to claim 1 wherein providing the electromagnetic interference shielding arrangement includes securing the shield wall to a surface of the first module.

14. The method according to claim 1 wherein providing the electromagnetic interference shielding arrangement is performed such that the inner portion of the shield wall at least partially surrounds a semiconductor component of the first module.

15. The method according to claim 1 wherein the shield wall is substantially formed of an electrically conductive material.

16. The method according to claim 15 wherein the electrically conductive material includes copper or aluminium.

17. A method of forming an intra-module electromagnetic interference shielding structure, the method comprising:
providing a strip including a first electronic package module and a second electronic package module spaced from the first electronic package module by a singulation line;
providing an electromagnetic interference shielding arrangement including a first portion over the first electronic package module and a second portion over the singulation line; and
singulating the first electronic package module along the singulation line thereby fracturing the second portion while keeping the first portion with the first electronic package module to define the intra-module electromagnetic interference shielding structure.

18. The method of claim 17 wherein the intra-module electromagnetic interference shielding structure includes a shield wall and a shield roof.

19. A method of forming an intra-module electromagnetic interference shielding structure, the method comprising:
providing a strip including a first electronic package module and a second electronic package module spaced from the first electronic package module by a singulation line;
providing an electromagnetic interference shielding arrangement including a first portion over the first electronic package module, a second portion over the singulation line, and a third portion over the second electronic package module; and
singulating the first electronic package module and the second electronic package module along the singulation line thereby fracturing the second portion while keeping the first portion with the first electronic package module to define a first intra-module electromagnetic interference shielding structure, and keeping the third portion with the second electronic package module to define a second intra-module electromagnetic interference shielding structure.

20. The method of claim 19 wherein the second portion extends between and connects the first portion and the third portion prior to singulating the first electronic package module and the second electronic package module.
